(19) United States
(12) Patent Application Publication
(10) Pub. No.: US 2024/0020444 A1
(43) Pub. Date: Jan. 18, 2024

(54) SYSTEMS AND METHODS FOR VISUALIZING THE TRANSPORT OF GROUND CONTAMINANTS IN AN AQUIFER

(71) Applicant: Battelle Memorial Institute, Columbus, OH (US)

(72) Inventors: Scott Rohrer, Brooklyn, NY (US); Joel Sminchak, Columbus, OH (US); James HICKS, PICKERINGTON, OH (US)

(21) Appl. No.: 18/352,448

(22) Filed: Jul. 14, 2023

Related U.S. Application Data
(60) Provisional application No. 63/389,036, filed on Jul. 14, 2022.

(51) Int. Cl. G06F 30/28

(52) U.S. Cl. CPC G06F 30/28

(57) ABSTRACT

In an approach to visualizing the transport of ground contaminants in an aquifer, a location and one or more aquifer properties are received from a user. One or more simulation parameters and one or more output parameters are received from the user. A transport simulation of the ground contaminants in the aquifer is performed. One or more output visualizations of the transport of the ground contaminants in the aquifer are generated.

### CROSS-REFERENCE TO RELATED APPLICATIONS

The present application claims the benefit of the filing date of U.S. Provisional Application Ser. No. 63/389,036, filed Jul. 14, 2022, the entire teachings of which application is hereby incorporated herein by reference.

### TECHNICAL FIELD

The present disclosure relates generally to systems and methods for simulating and visualizing ground contaminants and sources thereof. In particular, the present disclosure relates to systems and methods for visualizing the transport of ground contaminants in an aquifer.

### BACKGROUND

Ground contaminants may include per- and polyfluoroalkyl substances (PFAS), a group of manmade fluorinated chemicals that have been used in a variety of industries around the globe. Over 5000 types of PFAS are known, including PFOA (perfluorooctanoic acid), PFOS (perfluorooctane sulfonate), and GENX® (a synthetic short chain organofluorine compound). PFAS substances tend to be stable in the environment and can accumulate over time in the human body. As there is evidence that many PFAS chemicals can adversely affect human health, there is increasing interest in identifying not only the presence of PFAS in soil, surface water, groundwater, and drinking water, but also other vectors that can lead to human exposure. Finally, transport of the PFAS contamination plume is of interest, as such identification can be leveraged to guide remediation efforts, understand fate and transport, and to assign fiscal responsibility for such contamination to responsible parties.

### BRIEF DESCRIPTION OF THE DRAWINGS

Reference should be made to the following detailed description which should be read in conjunction with the following figures, wherein like numerals represent like parts.

FIG. 1 is a functional block diagram illustrating a distributed data processing environment consistent with the present disclosure.

FIG. 2 is an example of a graphical user interface (GUI) including a location input screen for the visualization program to select a location of an aquifer using an interactive map.

FIG. 3 is an example interactive chemical properties table for the visualization program for the user to select one or more chemicals of interest for the visualization program.

FIG. 4 is an example source screen for the visualization program to select contamination sources and observation points for the visualization program.

FIG. 5 is an example three-dimensional (3D) simulation output by the visualization program of the particle spread of the chemical of interest.

FIG. 6 is an example concentration output by the visualization program of the predicted concentration of the chemical of interest over time.

FIG. 7 is an example simulation parameters input screen for the visualization program to allow the user to select simulation control parameters for the simulation.

FIG. 8 is a flowchart diagram depicting operations for the visualization program, for visualizing the transport of ground contaminants in an aquifer, on the distributed data processing environment of FIG. 1, consistent with the present disclosure.

FIG. 9 depicts a block diagram of components of the computing device executing the visualization program within the distributed data processing environment of FIG. 1, consistent with the present disclosure.

### DETAILED DESCRIPTION

The present disclosure is not limited in its application to the details of construction and the arrangement of components set forth in the following description or illustrated in the drawings. The examples described herein may be capable of other embodiments and of being practiced or being carried out in various ways. Also, it may be appreciated that the phraseology and terminology used herein is for the purpose of description and should not be regarded as limiting as such may be understood by one of skill in the art. Throughout the present description, like reference characters may indicate like structure throughout the several views, and such structure need not be separately discussed. Furthermore, any particular feature(s) of a particular exemplary embodiment may be equally applied to any other exemplary embodiment(s) of this specification as suitable. In other words, features between the various exemplary embodiments described herein are interchangeable, and not exclusive.

Like many other ground contaminants, per- and polyfluoroalkyl chemicals have been recognized to have deleterious effects on human health, and there has been increasing pressure from the public and governmental sectors to identify the presence and types of ground contaminants in locations that may lead to human consumption or exposure, e.g., water supplies, soil, foodstuffs, etc. A per- and polyfluoroalkyl substance or chemical herein (collectively PFAS) may be understood as a fluorinated substance that contains at least one fully fluorinated methyl or methylene carbon atom, namely a chemical that includes at least a perfluorinated methyl group (—CF₃) or a perfluorinated methylene group (—CF₂—). Some examples of a PFAS may therefore include perfluorooctane sulfonic acid, N-methyl perfluorooctane sulfonamido ethanol, perfluorooctanoic acid, 8:2 fluorotelomer alcohol, perfluorobutane sulfonic acid, perfluorobutanoic acid, perfluorohexanoic acid.

PFAS substances tend to be stable in the environment and can accumulate over time in the human body. As there is evidence that many PFAS chemicals can adversely affect human health, there is increasing interest in identifying the presence and transport of PFAS in an aquifer. With that in mind, visualizing the transport of ground contaminants such as PFAS in an aquifer can be quite challenging and time consuming. There exists a need to simulate and visualize the transport of ground contaminants such as PFAS in an aquifer efficiently and accurately. The present disclosure is aimed at that need.

PFAS remediation requires data to guide the work of eliminating the persistent chemical contaminants. PFAS researchers and remediation experts need fate and transport data to perform the remediation work. Models exist that produce geo spatial data on the spread of PFAS through groundwater. Utilizing the existing models, however, is not currently an efficient process. Producing an assessment involves a difficult workflow and requires some technical proficiency. For existing models to run, input data must be tailored into a nonstandard file format.

Aspects of the present disclosure relate to systems and methods for visualizing the transport of ground contaminants, such as PFAS, in an aquifer. As will be described below, the systems described herein are tools for running groundwater fate and transport simulations. More specifically, embodiments provide a user interface for entering model parameters and a suite of automatically generated interactive geospatial visualizations of simulated plumes of ground contaminants. The result is an improved system to reduce the level of effort and the technical skills required to visualize the plumes of ground contaminants.

In an illustrated example embodiment, the system receives an aquifer location and aquifer properties. Aquifer properties may include, but are not limited to, a grid specification to be used during the simulation, the fraction of organic carbon content (i.e., the portion of the organic matter that is available to adsorb the organic contaminants of concern), porosity, clay content, bulk density (the mass of solids in the soil divided by the total volume), depositional system, and grain size distribution.

Next, the system receives simulation and output parameters. The simulation parameters may include, but are not limited to, one or more chemicals of interest and their properties, the sources of the data, and the properties of the source zone.

The chemical properties may include, but are not limited to, solubility, Kd (dissociation constant, which is defined as the amount of reactant that dissociates reversibly to form a component product), PFAS class, polarity behavior (affects solubility), molecular diffusion, and pKa (indication of acidity). Source zone properties may include, but are not limited to, the type of groundwater zone (slug, continuous, or disperse), size of the zone, concentrations, longitudinal dispersion coefficient, lateral dispersion coefficient, groundwater thickness, and concentration range.

Based on these inputs, the system then performs the simulation of the transport of ground contaminants in the aquifer. Based on the results of the simulation, the system then generates output visualizations, including 3D visualizations, of the transport of ground contaminants in the aquifer. For PFAS mitigation, chemists, hydrogeologists, and other researchers that need to study how the chemical properties of PFAS affect fate and transport, the disclosed system provides instantaneous simulations using unique methodologies tailored for PFAS. Unlike less technologically sophisticated modeling tools, the present disclosure provides 3D images of the projected plume movement over time, to allow the user to determine appropriate mitigation techniques quickly and accurately.

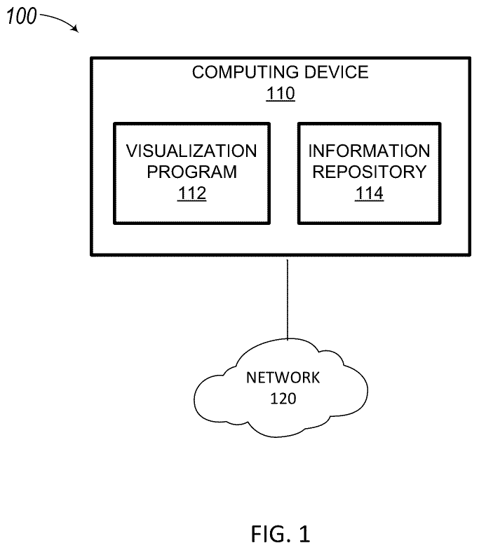

FIG. 1 is a functional block diagram illustrating a distributed data processing environment, generally designated 100, suitable for operation of visualization program 112 in accordance with at least one embodiment of the present disclosure. The term “distributed” as used herein describes a computer system that includes multiple, physically distinct devices that operate together as a single computer system. FIG. 1 provides only an illustration of one implementation and does not imply any limitations with regard to the environments in which different embodiments may be implemented. Many modifications to the depicted environment may be made by those skilled in the art without departing from the scope of the disclosure as recited by the claims.

Distributed data processing environment 100 includes computing device 110 optionally connected to network 120. Network 120 can be, for example, a telecommunications network, a local area network (LAN), a wide area network (WAN), such as the Internet, or a combination of the three, and can include wired, wireless, or fiber optic connections. Network 120 can include one or more wired and/or wireless networks that are capable of receiving and transmitting data, voice, and/or video signals, including multimedia signals that include voice, data, and video information. In general, network 120 can be any combination of connections and protocols that will support communications between computing device 110 and other computing devices (not shown) within distributed data processing environment 100.

Computing device 110 can be a standalone computing device, a management server, a web server, a mobile computing device, or any other electronic device or computing system capable of receiving, sending, and processing data. In an embodiment, computing device 110 can be a personal computer (PC), a desktop computer, a laptop computer, a tablet computer, a netbook computer, a smart phone, or any programmable electronic device capable of communicating with other computing devices (not shown) within distributed data processing environment 100 via network 120. In another embodiment, computing device 110 can represent a server computing system utilizing multiple computers as a server system, such as in a cloud computing environment. In yet another embodiment, computing device 110 represents a computing system utilizing clustered computers and components (e.g., database server computers, application server computers) that act as a single pool of seamless resources when accessed within distributed data processing environment 100.

In an embodiment, computing device 110 includes visualization program 112. In an embodiment, visualization program 112 is a program, application, or subprogram of a larger program for simulating and visualizing the transport of ground contaminants in an aquifer. In an alternative embodiment, visualization program 112 may be located on any other device accessible by computing device 110 via network 120.

In an embodiment, computing device 110 includes information repository 114. In an embodiment, information repository 114 may be managed by visualization program 112. In an alternate embodiment, information repository 114 may be managed by the operating system of the computing device 110, alone, or together with, visualization program 112. Information repository 114 is a data repository that can store, gather, compare, and/or combine information. In some embodiments, information repository 114 is located externally to computing device 110 and accessed through a communication network, such as network 120. In some embodiments, information repository 114 is stored on computing device 110. In some embodiments, information repository 114 may reside on another computing device (not shown), provided that information repository 114 is accessible by computing device 110. Information repository 114 includes, but is not limited to, system data and other data that is received by visualization program 112 from one or more sources, and data that is created by visualization program 112.

Information repository 114 may be implemented using any non-transitory volatile or non-volatile storage media for storing information, as known in the art. For example, information repository 114 may be implemented with random-access memory (RAM), solid-state drives (SSD), one or more independent hard disk drives, multiple hard disk drives in a redundant array of independent disks (RAID), optical library, or a tape library. Similarly, information repository 114 may be implemented with any suitable storage architecture known in the art, such as a relational database, an object-oriented database, or one or more tables.

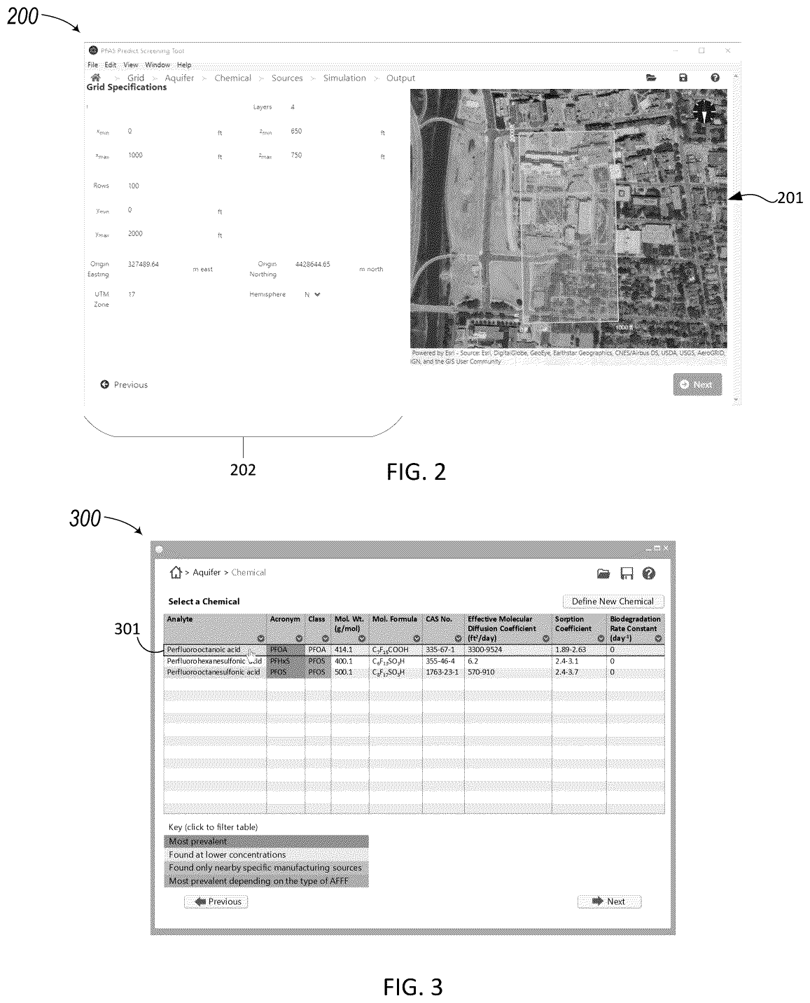

FIG. 2 is an example of a graphical user interface (GUI) including a location input screen 200 for the visualization program to select a location of an aquifer using an interactive map 201. In some embodiments, the system uses geographic information system (GIS) maps for the location input. A GIS is a type of database containing geographic data (that is, descriptions of phenomena for which location is relevant), combined with software tools for managing, analyzing, and visualizing those data. GIS provides the capability to relate previously unrelated information, through the use of location as the “key index variable”. Locations and extents that are found in the Earth's spacetime are able to be recorded through the date and time of occurrence, along with x, y, and z coordinates; representing, longitude (x), latitude (y), and elevation (z). All Earth-based, spatial—temporal, location and extent references should be relatable to one another, and ultimately, to a “real” physical location or extent.

The example location input screen 200 of FIG. 2 also includes grid specification 202. In this section of the location input screen 200 parameters may be entered by a user to specify the grid that will be used by the visualization program 112 to simulate and visualize plume migration of ground contaminants such as PFAS.

FIG. 3 is an example interactive chemical properties table 300 for the visualization program 112 for the user to select one or more chemicals of interest for the visualization program. The example chemical input screen of FIG. 3 displays three common chemicals that might be the subject of a plume analysis, but in actual use, any number of chemicals may be displayed. For example, row 301 shows perfluorooctanoic acid (PFOA). For each listed chemical, relevant properties are shown to aid the user in selecting the correct chemical. The user can filter the table using the displayed properties and can sort the table by any property. In addition, the user can define a new chemical for analysis if the desired chemical is not currently in the database.

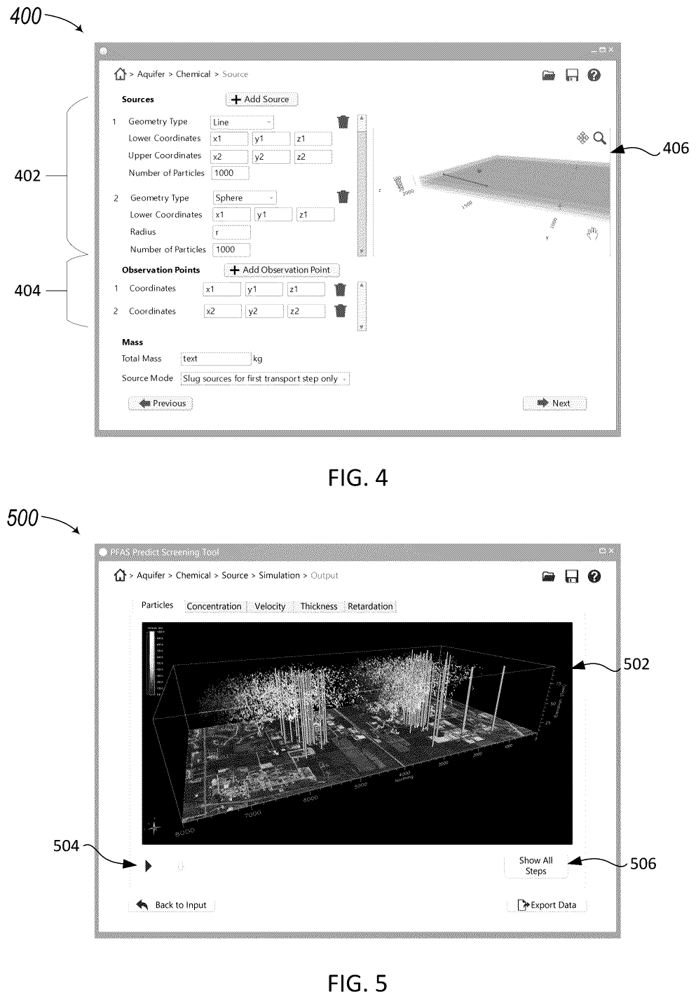

FIG. 4 is an example source screen 400 for the visualization program 112 to select contamination sources and observation points for the visualization program. In the example of FIG. 4, section 402 of the GUI allows for a user to input one or more sources of the chemical of interest. In some embodiments, the one or more sources may include parameters including, but not limited to, a geometry type, lower coordinates (i.e., x, y, and z coordinates) and upper coordinates for the source, and the number of particles of the source chemical detected. In the example of FIG. 4, 1,000 particles are displayed.

The example of FIG. 4 also allows for a user to input one or more observation points in section 404 of the GUI. These observation points are used by the visualization program 112 to generate the 3D plots for visualizing the transport of ground contaminants in an aquifer, e.g., PFAS, using known data representative of the chemical of interest groundwater transport properties and known data representative of the configuration of the specific aquifer associated with the visualization. In some embodiments, the user inputs the coordinates (i.e., x, y, and z coordinates) of one or more observation points. The example of FIG. 4 also includes visualization window 406, which is an interactive 3D visualization showing the position of layers, sources, and observation points. The visualization window 406 allows the user to visualize the scope of the analysis and thereby interactively adjust the input parameters to achieve the desired analysis.

FIG. 5 is an example 3D simulation output 500 by the visualization program 112 of the particle spread of the chemical of interest. In the example of FIG. 5, particle visualization 502 is an interactive particle visualization for the chemical of interest. The visualization program 112 generates the particle visualization 502 using known data representative of the chemical of interest groundwater transport properties and known data representative of the configuration of the specific aquifer associated with the visualization. Slider 504 allows the user to animate particle movement over time based on the output of the simulation. Steps button 506 allows the user to select from displaying particle locations at all time steps, as shown in the sample screen of FIG. 5, or showing the particle movement as selected by the user with slider 504. If the slider 504 mode is chosen, then the particle locations are displayed on particle visualization 502 for the selected time period by the position of the slider 504.

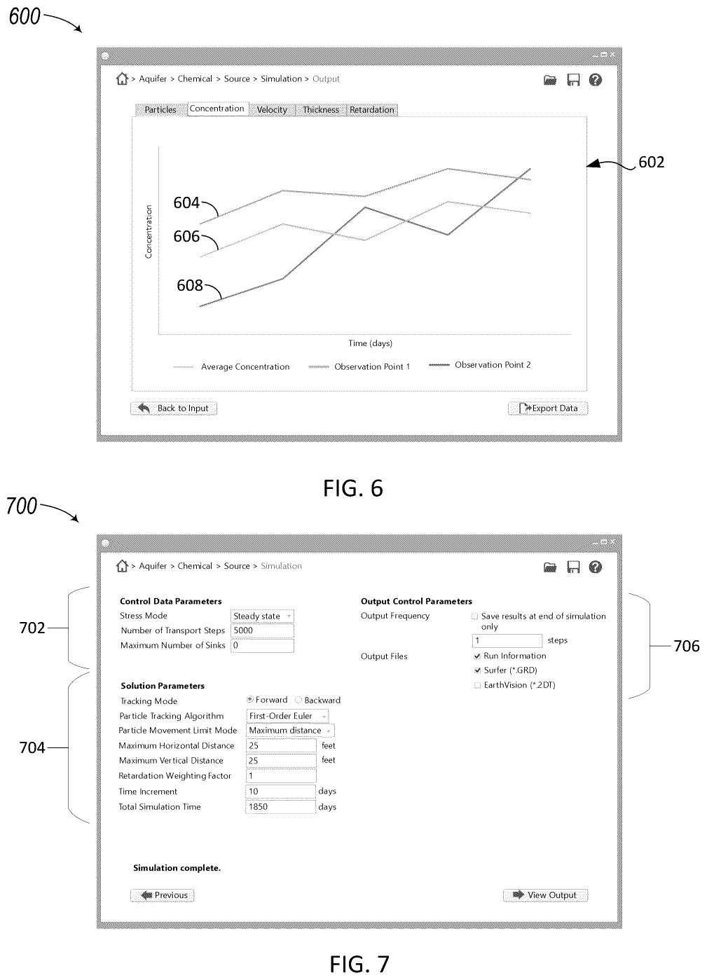

FIG. 6 is an example concentration output 600 by the visualization program 112 of the predicted concentration of the chemical of interest over time. In the example of FIG. 6, particle concentration 602 is a graph of the concentration of the chemical of interest graphed over the time interval of the simulation. The visualization program 112 generates the particle concentration 602 using known data representative of the chemical of interest groundwater transport properties and known data representative of the configuration of the specific aquifer associated with the visualization. This sample graph includes the average concentration 604, as well as the concentration of the chemical of interest as observed from observation point 1, i.e., trace 606, and from observation point 2, i.e., trace 608. It should be noted that although two observation points are displayed in this example, in actual use any number of observation points may be graphed.

FIG. 7 is an example simulation parameters input screen 700 for the visualization program 112 to allow the user to select simulation control parameters for the simulation. In the example of FIG. 7, the user can set control parameters 702, which may include, but are not limited to, parameters such as the stress mode, the number of transport steps, and the number of sinks. In solution parameters 704, the user can set solution parameters, which may include, but are not limited to, tracking mode, particle tracking algorithm, particle movement limit mode, maximum horizontal distance, maximum vertical distance, retardation weighting factor, time increment, and total simulation time. In output control parameters 706, the user can set output control parameters which may include, but are not limited to, output frequency and output file parameters. It should be noted that although control parameters 702, solution parameters 704, and output control parameters 706, are displayed in this example, in actual use any number of simulation control parameters may be available.

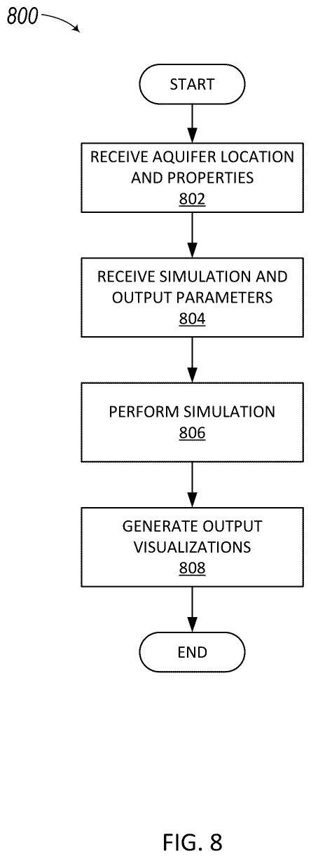

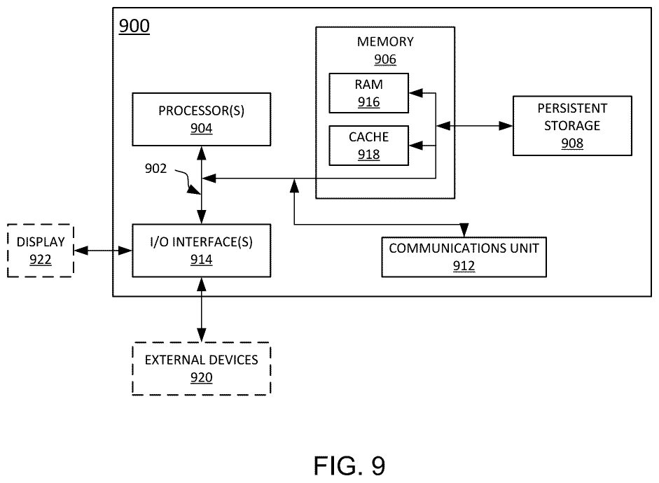

FIG. 8 is a flowchart diagram depicting operations for workflow 800, for visualizing the transport of ground contaminants in an aquifer, on the distributed data processing environment of FIG. 1, consistent with the present disclosure. In an alternative embodiment, the operations of workflow 800 may be performed by any other program while working with visualization program 112.

It should be appreciated that embodiments of the present disclosure provide at least for visualizing the transport of ground contaminants in an aquifer. However, FIG. 8 provides only an illustration of one implementation and does not imply any limitations with regard to the environments in which different embodiments may be implemented. Many modifications to the depicted environment may be made by those skilled in the art without departing from the scope of the disclosure as recited by the claims.

The visualization program 112 receives an aquifer location and properties (operation 802). In the illustrated example embodiment, the visualization program 112 receives an aquifer location and aquifer properties from a user. Aquifer properties may include, but are not limited to, a grid specification to be used during the simulation, the fraction of organic carbon content (i.e., the portion of the organic matter that is available to adsorb the organic contaminants of concern), porosity, clay content, bulk density (the mass of solids in the soil divided by the total volume), depositional system, and grain size distribution.

The visualization program 112 receives simulation and output parameters (operation 804). The visualization program 112 receives simulation and output parameters from the user that may include, but are not limited to, one or more chemicals of interest and their properties, the sources of the data, and the properties of the source zone.

The chemical properties may include, but are not limited to, solubility, Kd (dissociation constant, which is defined as the amount of reactant that dissociates reversibly to form a component product), PFAS class, polarity behavior (affects solubility), molecular diffusion, and pKa (indication of acidity). Source zone properties may include, but are not limited to, the type of groundwater zone (slug, continuous, or disperse), size of the zone, concentrations, longitudinal distance, lateral distance, groundwater thickness, and concentration range.

The visualization program 112 performs a simulation (operation 806). The visualization program 112 performs the simulation of the transport of ground contaminants such as PFAS in the aquifer based on the inputs received in operations 802 and 804 above.

The visualization program 112 generates output visualizations (operation 808). The visualization program 112 generates output visualizations, including 3D visualizations, of the transport of ground contaminants such as PFAS in the aquifer. These output visualizations may include the interactive particle visualization for the chemical of interest as shown in the example of FIG. 5 above, and the graph of the concentration of the chemical of interest graphed over the time interval of the simulation as shown in the example of FIG. 6 above. Other visualizations may include, but are not limited to, visualizations of the velocity of the plume of ground contaminants in the aquifer, the thickness of the plume, and retardation of the plume.

Once the visualization program 112 has generated all the visualizations requested by the user, the visualization program 112 then ends for this cycle.

FIG. 9 is a block diagram depicting components of one example of the computing device 110 suitable for visualization program 112, within the distributed data processing environment of FIG. 1, consistent with the present disclosure. FIG. 9 displays the computing device or computer 900, one or more processor(s) 904 (including one or more computer processors), a communications fabric 902, a memory 906 including, a random-access memory (RAM) 916 and a cache 918, a persistent storage 908, a communications unit 912, I/O interfaces 914, a display 922, and external devices 920. It should be appreciated that FIG. 9 provides only an illustration of one embodiment and does not imply any limitations with regard to the environments in which different embodiments may be implemented. Many modifications to the depicted environment may be made.

As depicted, the computer 900 operates over the communications fabric 902, which provides communications between the computer processor(s) 904, memory 906, persistent storage 908, communications unit 912, and input/output (I/O) interface(s) 914. The communications fabric 902 may be implemented with an architecture suitable for passing data or control information between the processors 904 (e.g., microprocessors, communications processors, and network processors), the memory 906, the external devices 920, and any other hardware components within a system. For example, the communications fabric 902 may be implemented with one or more buses.

The memory 906 and persistent storage 908 are computer readable storage media. In the depicted embodiment, the memory 906 comprises a RAM 916 and a cache 918. In general, the memory 906 can include any suitable volatile or non-volatile computer readable storage media. Cache 918 is a fast memory that enhances the performance of processor(s) 904 by holding recently accessed data, and near recently accessed data, from RAM 916.

Program instructions for visualization program 112 may be stored in the persistent storage 908, or more generally, any non-transitory computer readable storage media, for execution by one or more of the respective computer processors 904 via one or more memories of the memory 906. The persistent storage 908 may be a magnetic hard disk drive, a solid-state disk drive, a semiconductor storage device, flash memory, read only memory (ROM), electronically erasable programmable read-only memory (EEPROM), or any other computer readable storage media that is capable of storing program instruction or digital information.

The media used by persistent storage 908 may also be removable. For example, a removable hard drive may be used for persistent storage 908. Other examples include optical and magnetic disks, thumb drives, and smart cards that are inserted into a drive for transfer onto another computer readable storage medium that is also part of persistent storage 908.

The communications unit 912, in these examples, provides for communications with other data processing systems or devices. In these examples, the communications unit 912 includes one or more network interface cards. The communications unit 912 may provide communications through the use of either or both physical and wireless communications links. In the context of some embodiments of the present disclosure, the source of the various input data may be physically remote to the computer 900 such that the input data may be received, and the output similarly transmitted via the communications unit 912.

The I/O interface(s) 914 allows for input and output of data with other devices that may be connected to computer 900. For example, the I/O interface(s) 914 may provide a connection to external device(s) 920 such as a keyboard, a keypad, a touch screen, a microphone, a digital camera, and/or some other suitable input device. External device(s) 920 can also include portable computer readable storage media such as, for example, thumb drives, portable optical or magnetic disks, and memory cards. Software and data used to practice embodiments of the present disclosure, e.g., visualization program 112, can be stored on such portable computer readable storage media and can be loaded onto persistent storage 908 via the I/O interface(s) 914. I/O interface(s) 914 also connect to a display 922.

Display 922 provides a mechanism to display data to a user and may be, for example, a computer monitor. Display 922 can also function as a touchscreen, such as a display of a tablet computer.

The programs described herein are identified based upon the application for which they are implemented in a specific embodiment of the disclosure. However, it should be appreciated that any particular program nomenclature herein is used merely for convenience, and thus the disclosure should not be limited to use solely in any specific application identified and/or implied by such nomenclature.

The present disclosure may be a system, a method, and/or a computer program product. The system or computer program product may include a computer readable storage medium (or media) having computer readable program instructions thereon for causing a processor to carry out aspects of the present disclosure.

The computer readable storage medium can be any tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a RAM, a ROM, an EPROM or Flash memory, a Static Random Access Memory (SRAM), a portable Compact Disc Read-Only Memory (CD-ROM), a Digital Versatile Disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, Instruction-Set-Architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some embodiments, electronic circuitry including, for example, programmable logic circuitry, Field-Programmable Gate Arrays (FPGA), or other Programmable Logic Devices (PLD) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, a special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operations to be performed on the computer, other programmable apparatus, or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

According to one aspect of the disclosure there is thus provided a computer-implemented method for visualizing transport of ground contaminants in an aquifer, the computer-implemented method including: receiving, by one or more computer processors, from a user a location and one or more aquifer properties; receiving, by the one or more computer processors, from the user, one or more simulation parameters and one or more output parameters; performing, by the one or more computer processors, a transport simulation of the ground contaminants in the aquifer; and generating, by the one or more computer processors, one or more output visualizations of the transport of the ground contaminants in the aquifer.

According to another aspect of the disclosure, there is provided a system for visualizing transport of ground contaminants in an aquifer, the system including: one or more computer processors; one or more computer readable storage media; and program instructions stored on the one or more computer readable storage media for execution by at least one of the one or more computer processors, the stored program instructions including instructions to: receive from a user a location and one or more aquifer properties; receive from the user, one or more simulation parameters and one or more output parameters; perform a transport simulation of the ground contaminants in the aquifer; and generate one or more output visualizations of the transport of the ground contaminants in the aquifer.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the disclosure. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A computer-implemented method for visualizing transport of ground contaminants in an aquifer, the computer-implemented method comprising:
receiving, by one or more computer processors, a location and one or more aquifer properties from a user;
receiving, by the one or more computer processors, one or more simulation parameters and one or more output parameters from the user;
performing, by the one or more computer processors, a transport simulation of the ground contaminants in the aquifer; and
generating, by the one or more computer processors, one or more output visualizations of the transport of the ground contaminants in the aquifer.

2. The computer-implemented method of claim 1, wherein the one or more output visualizations of the transport of the ground contaminants in the aquifer are three-dimensional (3D) visualizations.

3. The computer-implemented method of claim 2, wherein the 3D visualizations include at least one of an interactive particle visualization for a chemical of interest and a graph of a concentration of the chemical of interest graphed over a time interval of the transport simulation.

4. The computer-implemented method of claim 1, wherein the one or more aquifer properties include at least one of a grid specification to be used during the transport simulation, a fraction of organic carbon content, a porosity, a clay content, a bulk density, a depositional system, and a grain size distribution.

5. The computer-implemented method of claim 1, wherein the one or more simulation parameters include at least one of, one or more chemicals of interest, one or more chemical properties, one or more sources, and one or more source zone properties.

6. The computer-implemented method of claim 5, wherein the one or more chemical properties include at least one of a solubility, a dissociation constant (Kd), a PFAS class, a polarity behavior, a molecular diffusion, and a pKa.

7. The computer-implemented method of claim 5, wherein the one or more source zone properties include at least one of a type of groundwater zone, a size of a source zone, one or more concentrations, a longitudinal distance, a lateral distance, a groundwater thickness, and a concentration range.

8. The computer-implemented method of claim 5, wherein:
the one or more chemicals of interest are selected from a table;
the user can filter the table using one or more displayed properties; and
the user can sort the table by any of the one or more displayed properties.

9. The computer-implemented method of claim 1, wherein the location of the aquifer is an interactive 3D visualization showing a position of one or more layers, one or more sources, and one or more observation points of a source zone of the aquifer.

10. The computer-implemented method of claim 1, wherein the user selects the location of the aquifer using an interactive map.

11. The computer-implemented method of claim 10, wherein the interactive map is a geographic information system (GIS) map.

12. The computer-implemented method of claim 1, wherein the ground contaminants are per- and polyfluoroalkyl substances (PFAS).

13. A system for visualizing transport of ground contaminants in an aquifer, the system comprising:
one or more computer processors;
one or more computer readable storage media; and
program instructions stored on the one or more computer readable storage media for execution by at least one of the one or more computer processors, the stored program instructions including instructions to:
receive a location and one or more aquifer properties from a user;
receive one or more simulation parameters and one or more output parameters from the user;
perform a transport simulation of the ground contaminants in the aquifer; and
generate one or more output visualizations of the transport of the ground contaminants in the aquifer.

14. The system of claim 13, wherein the one or more output visualizations of the transport of the ground contaminants in the aquifer are three-dimensional (3D) visualizations.

15. The system of claim 14, wherein the 3D visualizations include at least one of an interactive particle visualization for a chemical of interest and a graph of a concentration of the chemical of interest graphed over a time interval of the transport simulation.

16. The system of claim 13, wherein:
the one or more aquifer properties include at least one of a grid specification to be used during the transport simulation, a fraction of organic carbon content, a porosity, a clay content, a bulk density, a depositional system, and a grain size distribution;
the one or more simulation parameters include at least one of, one or more chemicals of interest, one or more chemical properties, one or more sources, and one or more source zone properties;
the one or more chemical properties include at least one of a solubility, a dissociation constant (Kd), a PFAS class, a polarity behavior, a molecular diffusion, and a pKa; and
the one or more source zone properties include at least one of a type of groundwater zone, a size of a source zone, one or more concentrations, a longitudinal distance, a lateral distance, a groundwater thickness, and a concentration range.

17. The system of claim 16, wherein:
the one or more chemicals of interest are selected from a table;
the user can filter the table using one or more displayed properties; and
the user can sort the table by any of the one or more displayed properties.

18. The system of claim 13, wherein the location of the aquifer is an interactive 3D visualization showing a position of one or more layers, one or more sources, and one or more observation points of a source zone of the aquifer.

19. The system of claim 13, wherein:
the user selects the location of the aquifer using an interactive map; and
the interactive map is a geographic information system (GIS) map.

20. The system of claim 13, wherein the ground contaminants are per- and polyfluoroalkyl substances (PFAS).
